(19) United States
(12) Patent Application Publication
(10) Pub. No.: US 2025/0183054 A1
(43) Pub. Date: Jun. 5, 2025

(54) SELECTIVE BOTTOM-UP FILL

(71) Applicant: ASM IP Holding B.V., Almere (NL)

(72) Inventors: Guannan Chen, Phoenix, AZ (US); Jiyeon Kim, Mesa, AZ (US); YoungChol Byun, Tempe, AZ (US); Jacqueline Wrench, Mesa, AZ (US); Jonathan Bakke, Phoenix, AZ (US); Paul Ma, Scottsdale, AZ (US); Tieyi Lu, Chandler, AZ (US); Jaebeom Lee, Tempe, AZ (US); Moataz Bellah Mousa, Chandler, AZ (US)

(21) Appl. No.: 18/958,166

(22) Filed: Nov. 25, 2024

Related U.S. Application Data
(60) Provisional application No. 63/604,777, filed on Nov. 30, 2023.

(51) Int. Cl. H01L 21/3205; C23C 16/04; C23C 16/44; C23C 16/455; H01L 21/02; H01L 21/3213

(52) U.S. Cl. CPC H01L 21/32051; C23C 16/045; C23C 16/4408; C23C 16/45553; H01L 21/02068; H01L 21/32135

(57) ABSTRACT

Disclosed is a method, system and apparatus for filling a gap feature on a substrate surface, comprising providing a substrate with a surface comprising a gap feature in a reaction chamber, depositing a first material layer into the gap feature with a first cyclic deposition process, etching the first material layer to form a base in a bottom portion of the gap feature with a cyclic etching process and partially filling the gap feature with a second material layer with a second cyclic deposition process.

### CROSS-REFERENCE TO RELATED APPLICATIONS

This application is a nonprovisional of, and claims priority to and the benefit of, U.S. Provisional Patent Application No. 63/604,777, filed Nov. 30, 2023 and entitled “SELECTIVE BOTTOM-UP FILL,” which is hereby incorporated by reference herein.

### FIELD OF INVENTION

The present disclosure relates generally to methods for filling a gap feature on a substrate surface and particularly to methods for filling one or more gap features with a metal film utilizing selective bottom-up fill deposition processes. The present disclosure also generally relates to semiconductor device structures including one or more gap features filled with a metal film.

### BACKGROUND OF THE DISCLOSURE

Semiconductor fabrication processes for forming semiconductor device structures, for example, transistors, memory elements, and integrated circuits, are wide ranging and may include deposition processes, etch processes, thermal annealing processes, lithography processes, and doping processes, amongst others.

A particular semiconductor fabrication process commonly utilized is the deposition of a metal film into a gap feature thereby filling the gap feature (which may include a gap, a trench, a via, and the like) with the metal film, a process commonly referred to as “gap fill.” Substrates used during the manufacture of semiconductor devices may comprise a multitude of gap features on a substrate with a non-planar surface. The gap features may comprise substantially vertical gap features being disposed between protruding portions of the substrate surface or indentations formed in a substrate surface. The gap features may also comprise substantially horizontal gap features being disposed between two adjacent materials bounding the horizontal gap feature. As semiconductor device structure geometries have decreased and high aspect ratio features have become more common place in such semiconductor device structures as DRAM, flash memory, and logic, it has become increasingly difficult to fill the multitude of gap features with a metal having the desired characteristics.

Deposition methods such as high density plasma (HDP), sub-atmospheric chemical vapor deposition (SACVD), and low pressure chemical vapor deposition (LPCVD) have been used for gap fill processes, but these processes commonly do not achieve the desired gap fill capability.

Accordingly, methods and associated semiconductor device structures are desired for filling gap features on a non-planar substrate with a gap fill metal with improved characteristics.

### SUMMARY OF THE DISCLOSURE

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

In one aspect, a method for filling a gap feature on a substrate surface, includes providing a substrate with a surface and a gap feature in a reaction chamber, depositing a first material layer into the gap feature with a first cyclic deposition process, etching the first material layer to form a base in a bottom portion of the gap feature with a cyclic etching process, and partially filling the gap feature with a second material layer with a second cyclic deposition process.

The method may also include where the base is a metal base and includes a metal selected from the group consisting of titanium nitride (TiN), molybdenum nitride (MoN), tungsten nitride (WN), vanadium nitride (VN), niobium nitride (NbN), tantalum nitride (TaN), hafnium nitride (HfN), zirconium nitride (ZrN), molybdenum (Mo), tungsten (W), fluorine-free W (FFW), ruthenium (Ru), cobalt (Co), copper (Cu), or a doped metal nitride.

The method may also include where the first cyclic deposition process includes contacting the substrate with a first vapor phase precursor, contacting the substrate with a second vapor phase precursor, and purging the chamber.

The method may also include where the cyclic etching process includes contacting the substrate with a first halide, and purging the chamber.

The method may also include where the first vapor phase precursor includes at least one of titanium tetrachloride (TiCl4), titanium tetraiodide (TiI4), titanium tetrabromide (TiBr3), hafnium tetrachloride (HfCl4), boron trichloride (BCl3), aluminum trichloride (AlCl3), silicon tetrachloride (SiCl4), disilicon hexachloride (Si2Cl6), trisilicon octochloride (Si3Cl8), dichlorosilane (SiH2Cl2), NiCl2(TMPDA), 2-methylcyclohexa-2,5-diene-1,4-diyl)bis(trimethylsilane) (Cl3H26Si2), triethyl borate (B(OCH2CH3)3), gallium monochloride (GaCl), gallium trichloride (GaCl3), niobium pentachloride (NbCl5), molybdenum tetrachloride (MoCl4), molybdenum pentachloride (MoCl5), molybdenum (V) trichloride oxide (MoOCl3), molybdenum (VI) tetrachloride oxide (MoOCl4), molybdenum (IV) dichloride dioxide (MoO2Cl2), indium trichloride (InCl3), tantalum pentachloride (TaCl5), tungsten hexachloride (WCl6), vanadium fluoride (VF3), vanadium chloride (VCl3), vanadium oxychloride (VOCl3), or zirconium tetrachloride (ZrCl4), or combinations thereof.

The method may also include where the second vapor phase precursor includes at least one of hydrogen (H2), molecular nitrogen (N2), ammonia (NH3), hydrazine (N2H4), a hydrazine derivative, a nitrogen-based plasma, an alkyl-hydrazine, tertbutylhydrazine (C4H9N2H3), methylhydrazine (CH3NHNH2), dimethylhydrazine ((CH3)2N2H2), a nitrogen-based plasma, atomic nitrogen (N), nitrogen ions, nitrogen radicals, or excited species of nitrogen.

The method may also include contacting a top portion of the substrate with an inhibitor.

The method may also include where the inhibitor includes at least one of allyltrimethylsilane (TMS-A), chlorotrimethylsilane (TMS-Cl), N-(trimethylsilyl)imidazole (TMS-Im), octadecyltrichlorosilane (ODTCS), hexamethyldisilazane (HMDS), N-(trimethylsilyl) dimethylamine (TMSDMA) or trimethylchlorosilane, or a combination thereof.

The method may also include further includes contacting an exposed surface of the first material layer with an oxidizer.

The method may also include where the oxidizer includes at least one of: water (H2O), hydrogen peroxide (H2O2), ozone (O3), oxygen (O2), O2 plasma, alcohol, alkyl alcohol, ethanol, methanol, butanol, isobutanol, isopropanol, or a combination thereof.

The method may also include where the first halide includes molybdenum pentachloride (MoCl5), NF3, tungsten chloride (WCl5), chlorine (C12), niobium chloride (NbCl5), titanium tetrachloride (TiCl4), vanadium tetrachloride (VCl4), tantalum pentachloride (TaCl5), hafnium tetrachloride (HfCl4), niobium fluoride (NbF5), tantalum chloride (TaCl5), or tantalum fluoride (TaF5), or a combination thereof.

The method may also include where the first halide includes MoCl5, NF3, NbCl5 or WCl5.

The method may also include where the first halide vessel temperature is between 100° C.-150° C.

The method may also include where the second cyclic deposition process includes contacting the substrate with a second halide, contacting the substrate with co-reactant, and purging the chamber.

The method may also include where the second halide includes at least one MoCl5, MoCl4, MoO2Cl2 or MoOCl4.

The method may also include where the first halide and the second halide are the same.

The method may also include where a surface clean step includes contacting an exposed surface within the gap feature with an etching gas. The method may also include where the etching gas is a plasma of NF3.

The method may also include where the co-reactant includes at least one of H2, N2, ammonia (NH3), hydrazine (N2H4), silane (SiH4), disilane (Si2H6), trisilane (Si3H8), germane (GeH4), digermane (Ge2H6), borane (BH3), diborane (B2H6), 1-methyl-3,6-bis(trimethylsilyl)-1,4-cyclohexadiene (C13H26Si2) or hydrogen excited species.

The method may also include where the co-reactant includes H2. Other technical features may be readily apparent to one skilled in the art from the following figures, descriptions, and claims.

For purposes of summarizing the invention and the advantages achieved over the prior art, certain objects and advantages of the invention have been described herein above. Of course, it is to be understood that not necessarily all such objects or advantages may be achieved in accordance with any particular example of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these examples are intended to be within the scope of the invention herein disclosed. These and other examples will become readily apparent to those skilled in the art from the following detailed description of certain examples having reference to the attached figures, the invention not being limited to any particular example(s) disclosed.

### BRIEF DESCRIPTION OF THE DRAWING FIGURES

While the specification concludes with claims particularly pointing out and distinctly claiming what are regarded as examples of the invention, the advantages of examples of the disclosure may be more readily ascertained from the description of certain examples of the examples of the disclosure when read in conjunction with the accompanying drawings, in which:

FIG. 1 illustrates a schematic diagram of a reactor system, in accordance with an example of the present technology.

FIG. 2 illustrates a schematic diagram of a reactor system having multiple reaction chambers, in accordance with an example of the present technology.

FIG. 3 illustrates simplified cross-sectional schematic diagrams of semiconductor structures formed during cyclic processes, in accordance with an example of the present technology.

FIG. 4 illustrates simplified cross-sectional schematic diagrams of semiconductor structures formed during cyclic processes, in accordance with an example of the present technology.

FIG. 5 illustrates simplified cross-sectional schematic diagrams of semiconductor structures formed during cyclic processes, in accordance with an example of the present technology.

FIG. 6 illustrates a processing method, in accordance with an example of the present technology.

FIG. 7 illustrates a processing method, in accordance with an example of the present technology.

FIG. 8 illustrates a processing method, in accordance with an example of the present technology.

FIG. 9 illustrates a processing method, in accordance with an example of the present technology.

FIG. 10 illustrates a processing method, in accordance with an example of the present technology.

FIG. 11 illustrates a processing method, in accordance with an example of the present technology.

### DETAILED DESCRIPTION

The detailed description of various examples herein makes reference to the accompanying drawings, which show the exemplary examples by way of illustration. While these exemplary examples are described in sufficient detail to enable those skilled in the art to practice the disclosure, it should be understood that other examples may be realized and that logical, chemical, and/or mechanical changes may be made without departing from the spirit and scope of the disclosure. Thus, the detailed description herein is presented for purposes of illustration only and not of limitation. For example, the steps recited in any of the method or process descriptions can be executed in any combination and/or order and are not limited to the combination and/or order presented. Further, one or more steps from one of the disclosed methods or processes can be combined with one or more steps from another of the disclosed methods or processes in any suitable combination and/or order. Moreover, any of the functions or steps can be outsourced to or performed by one or more third parties. Furthermore, any reference to singular includes plural examples, and any reference to more than one component can include a singular example.

Although certain examples are disclosed below, it will be understood by those in the art that the disclosure extends beyond the specifically disclosed examples and/or uses of the disclosure and obvious modifications and equivalents thereof. Thus, it is intended that the scope of the disclosure should not be limited by the particular examples described herein.

The illustrations presented herein are not meant to be actual views of any particular material, apparatus, structure, or device, but are merely representations that are used to describe examples of the disclosure.

As used herein, the term “substrate” can refer to any underlying material or materials that may be used, or upon which, a device, a circuit, or a film/layer may be formed.

As used herein, the term “atomic layer deposition” (ALD) can refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) can subsequently be introduced into the process chamber for use in converting the chemisorbed precursor to the desired material on the deposition surface. Typically, this reactant is capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) can refer to any process wherein a substrate is exposed to one or more volatile precursors, which react and/or decompose on a substrate surface to produce a desired deposition.

As used herein, the term “cyclic deposition” may refer to the sequential introduction of one or more precursors and/or reactants into a reaction chamber to deposit a film over a substrate and includes deposition techniques such as atomic layer deposition and cyclic chemical vapor deposition.

As used herein, the term “cyclic chemical vapor deposition” may refer to any process wherein a substrate is sequentially exposed to one or more volatile precursors, which react and/or decompose on a substrate to produce a desired deposition.

As used herein, the term “gap feature” may refer to an opening or cavity disposed between two surfaces of a substrate. The term “gap feature” may refer to an opening or cavity disposed between opposing inclined sidewalls of two protrusions, such as gaps, vias, trenches, and the like, extending vertically from the surface of the substrate or opposing inclined sidewalls of an indentation extending vertically into the surface of the substrate, such a gap feature may be referred to as a “gap feature.” The term “gap feature” may also refer to an opening or cavity disposed between two opposing substantially horizontal surfaces, the horizontal surfaces bounding the horizontal opening or cavity; such a gap feature may be referred to as a “horizontal gap feature.”

As used herein, the terms “layer,” “film,” and/or “thin film” can refer to any continuous or non-continuous structures and material deposited by the methods disclosed herein. For example, “layer,” “film,” and/or “thin film” could include 2D materials, nanorods, nanotubes, or nanoparticles or even partial or full molecular layers or partial or full atomic layers or clusters of atoms and/or molecules. “Layer,” “film,” and/or “thin film” can comprise material or a layer with pinholes, but still be at least partially continuous.

A number of example materials are given throughout the examples of the current disclosure, it should be noted that the chemical formulas given for each of the example materials should not be construed as limiting and that the non-limiting example materials given should not be limited by a given example stoichiometry.

The present disclosure includes methods for filling one or more gap features on a substrate surface and particularly methods for filling one or more gap features with a metal film utilizing a cyclic deposition-etch process. Such films may be utilized in a number of applications, such as, for example, low electrical resistivity gap-fill, liner layers for 3D-NAND, DRAM word-line features, DRAM buried word-line features or as an interconnect material in CMOS logic applications. The ability to deposit a metal film in a gap feature may allow for lower effective electrical resistivity for interconnects in logic applications, i.e., CMOS structures, and word-line/bit-line in memory applications, such as 3D-NAND and DRAM structures.

Further, in this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, or the like. Further, in this disclosure, the terms “including,” “constituted by” and “having” can refer independently to “typically or broadly comprising,” “comprising,” “consisting essentially of,” or “consisting of” in some examples. In this disclosure, any defined meanings do not necessarily exclude ordinary and customary meanings in some examples.

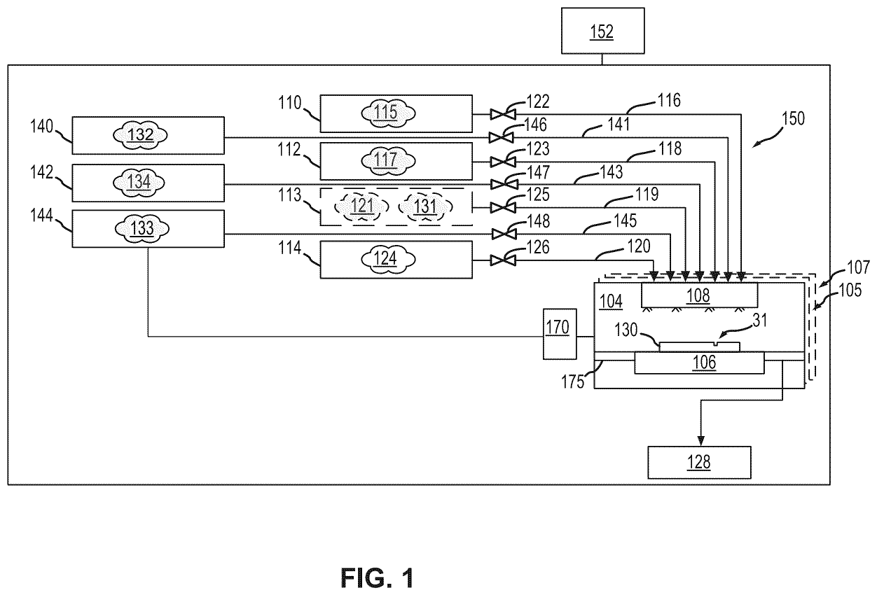

FIG. 1 is a schematic illustration representing an abstraction of an example reactor system 150. Reactor system 150 may comprise one or more reaction chambers 104, 105 and 107, each housing a susceptor 106 to hold a substrate 130 (including at least one feature 31) during processing, a fluid distribution system 108 (e.g., a showerhead) to distribute one or more reactants to a surface of substrate 130. Reactor system 150 may include a direct plasma source 175 incorporated within any of chambers 104, 105 or 107 and/or a remote plasma source 170 coupled to any of chambers 104, 105 or 107. Multiple deposition and/or etching processes may be carried out in a single reaction chamber 104 and/or various processes may be carried out in separate reaction chambers 104, 105 and/or 107.

For simplicity, reactant sources and carrier/purge gas sources are shown coupled to a single reaction chamber 104, however, it should be understood that reactant sources and carrier/purge gases for separate processes may be coupled to respective reaction chambers for those specific processes.

In an example, reactant sources vessels 110, 112, 113, 140, 142, 144 and/or a carrier or purge gas source vessel 114, may be fluidly coupled to reaction chamber 104 via respective lines 116, 118, 119, 141, 143, 145, and 120, and respective valves or controllers 122, 123, 125, 146, 147, 148, and 126. Reactant gases (e.g., first vapor phase precursor 115, second vapor phase precursor 117, inhibitor 121 or oxidizer 131, halide 132, precursor 134 (precursor 134 may be a co-reactant in certain embodiments), and/or etchant 133) or other materials from respective source vessels can be applied to substrate 130 in reaction chamber 104. Carrier or purge gas 124 from gas source vessel 114 may be an inert gas and can be flowed to and through reaction chamber 104 to remove any excess reactant or other undesired materials from reaction chamber 104. System 150 can also comprise a vacuum source 128 fluidly coupled to the reaction chamber 104, which can be configured to evacuate reactants, a purge gas, or other materials out of reaction chamber 104. Carrier or purge gas 124 may comprise argon, helium, neon, krypton, nitrogen and/or xenon, or the like, or combination thereof.

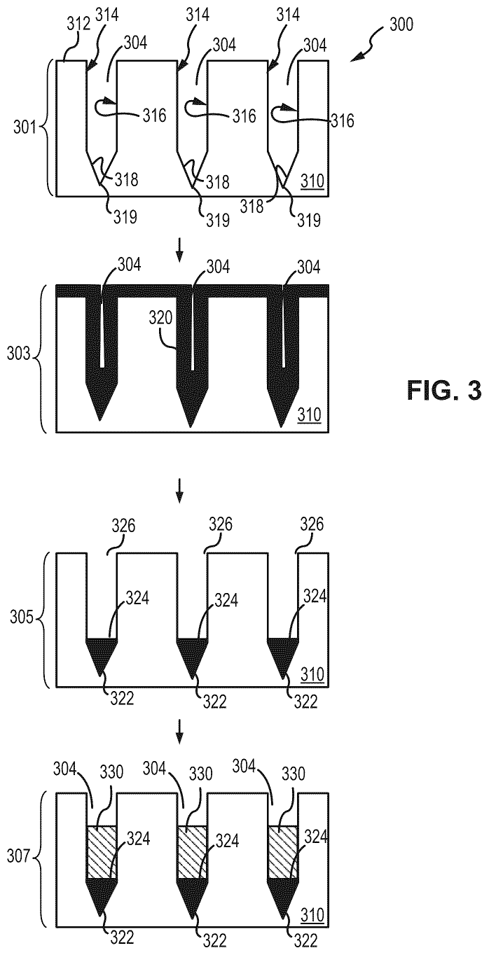

In an example, controller 152 can be configured to perform various functions and/or steps as described herein. Controller 152 can include one or more microprocessors, memory elements, and/or switching elements to perform the various functions. Although illustrated as a single unit, controller 152 can alternatively comprise multiple devices. By way of example, controller 152 can be used to control gas flow (e.g., by monitoring flow rates and controlling valves 122, 123, 125, 126, 146, 147, and/or 148), motors, showerhead 108, remote plasma source 170, heaters, cooling devices and/or vacuum source 128 to execute various processes (e.g., processes 300, 400, 500, 600, 700, 800, 900, 1000 and/or 1100 shown in respective FIGS. 3, 4, 5, 6, 7, 8, 9, 10 and/or 11). Further, when a system includes two or more reaction chambers, as described in more detail below, the two or more reaction chambers can be coupled to the same/shared controller.

In an example, system 150 may perform a gap filling process to selectively deposit metal into a gap feature or recess 31 of a substrate. The process may comprise a plurality of sub-cycles starting with depositing a thin metal nitride layer, then etching the metal nitride layer to a base in a lower portion of the gap feature, and finally depositing the metal layer on the metal nitride base.

In a first sub-cycle, depositing the metal nitride layer within a recess 31 of substrate 130 may comprise pulsing first vapor phase precursor 115 from reactant source vessel 110 to reaction chamber 104 via showerhead 108. Second vapor phase precursor 117 may be pulsed with or separately from first vapor phase precursor 115 from reactant source vessel 112 to reaction chamber 104 via showerhead 108. As first vapor phase precursor 115 and second vapor phase precursor 117 contact substrate 130 a nitride may form on substrate 130 within recess 31. To inhibit deposition of metal nitride at the top and/or outside of the recess an inhibitor 121 may also be pulsed into chamber 104 from reactant source vessel 113. Inhibitor 121 may be flowed into the chamber 104 separately from first vapor phase precursor 115 and/or second vapor phase precursor 117 or simultaneously with one or more of the first vapor phase precursor 115 and/or the second vapor phase precursor 117. In an example, inhibitor 121 may be flowed into chamber 104 subsequent to flowing second vapor phase precursor 117 into chamber 104. In another example, inhibitor 121 may be flowed into chamber 104 simultaneously with flowing second vapor phase precursor 117 into chamber 104.

Inhibitor 121 may be selected to preferentially deposit at an opening of the recess 31 so as to prevent oxide from forming at the opening to the recess 31 to a greater extent than within recess 31. Reduction in deposition at the opening of recess 31 may reduce formation of gaps or seams in oxide deposited therein.

In an example, metal nitride materials such as first vapor phase precursor 115 and second vapor phase precursor 117 may be deposited in the same chamber as inhibitor 121 or may be deposited in different chambers.

The metal nitride gap fill layer may be formed by any of a variety of methods including various deposition cycles including pulsing first vapor phase precursor 115, inhibitor 121 and/or second vapor phase precursor 117 into the chamber and purging the chamber with a purge gas 124 between one or more pulses and/or between one or more deposition cycles. Such a deposition cycle (or portions thereof) may be repeated until a desired thickness of deposited nitride is disposed within recess 31. First vapor phase precursor 115, inhibitor 121 and/or second vapor phase precursor 117 may be pulsed into the chamber in various orders and/or one or more may be pulsed simultaneously. For example, a deposition cycle for forming metal nitride within recess 31 may comprise pulsing a first vapor phase precursor 115 into chamber 104, purging chamber 104 with purge gas 124 and then pulsing an inhibitor 121 and a second vapor phase precursor 117 into chamber 104 simultaneously and purging chamber 104 with purge gas 124 at various intervals. In another example, a deposition cycle for forming an oxide within recess 31 may comprise pulsing inhibitor 121 into chamber 104 to inhibit deposition of metal nitride at various areas on outer portions or top portions of recess 31, first vapor phase precursor 115 may then be pulsed into chamber 104, purging chamber 104 with purge gas 124, then pulsing inhibitor 121, then purging chamber 104 with purge gas 124 and finally pulsing second vapor phase precursor 117 into chamber 104 simultaneously. Chamber 104 may be purged with purge gas 124 at various intervals (e.g., between pulses or deposition cycles).

Another optional process may be pulsing of oxidizer 131 from reactant source 113 to oxidize an exposed surface of deposited metal nitride (e.g., to enhance etching in the next sub-cycle).

Inhibitor 121 and oxidizer 131 are indicated to be optional reactants by dashed lines. To clarify, if reactant source vessel 113 contains inhibitor 121, it would not also contain oxidizer 131 unless inhibitor 121 and oxidizer 131 are the same species. Inhibitor 121 and oxidizer 131 may be used in the same process as both are optional. In such a case, each would be contained in respective reactant source vessels.

In an example, chamber 104 may be purged with purge gas 124 before, after, between, one or more pulses of any of first vapor phase precursor 115, second vapor phase precursor 117 inhibitor 121 and oxidizer 131 and/or between one or more sub-cycles. The deposition sub-cycle (or portions thereof) may be repeated until a desired thickness of metal nitride layer is disposed within recess 31.

In the etching sub-cycle, the metal nitride may be etched to leave a metal nitride plug in the bottom portion of recess 31 of substrate 130. The etching sub-cycle may comprise pulsing halide 132 from reactant source vessel 140 to reaction chamber 104 via showerhead 108.

In some examples, the etched metal nitride plug may be exposed an additional etching gas 133 (e.g., low power NF3 plasma) to remove unwanted residues.

In an example, chamber 104 may be purged with purge gas 124 before, after, between, one or more pulses of halide 132 and/or etching gas 133 and/or between one or more sub-cycles. The etching sub-cycle (or portions thereof) may be repeated until a desired thickness of metal nitride base (or plug) is disposed within recess 31.

In a second deposition sub-cycle, a metal may be selectively deposited on the metal nitride base in the bottom portion of recess 31 of substrate 130. The second deposition sub-cycle may comprise pulsing halide 132 from reactant source vessel 140 to reaction chamber 104 via showerhead 108. Precursor 134 may be pulsed with or separately from halide 132 from reactant source vessel 142 to reaction chamber 104 via showerhead 108. As halide 132 and precursor 134 contact substrate 130 a metal may form on the metal nitride base within recess 31. In an example, chamber 104 may be purged with purge gas 124 before, after, between, one or more pulses of halide 132 and/or precursor 134 and/or between one or more second deposition sub-cycles. The second deposition sub-cycle (or portions thereof) may be repeated until a desired thickness of the metal is disposed within recess 31.

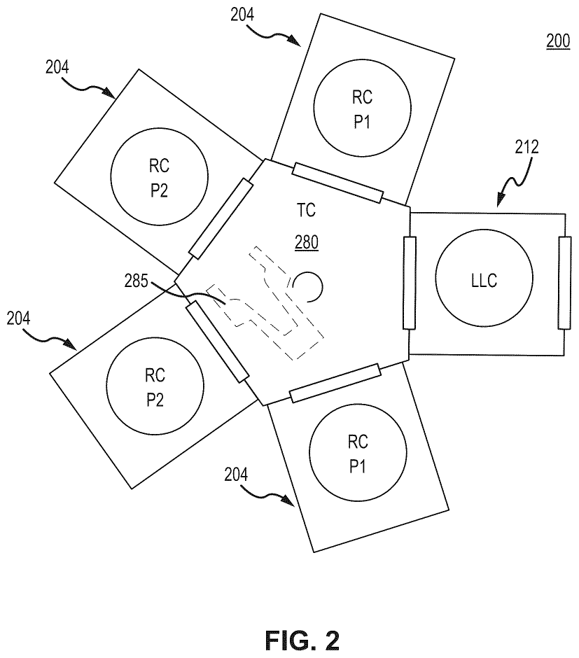

In some examples, a reactor system (e.g., reactor system 150) can comprise multiple reaction chambers. For example, in reactor system 200, shown in FIG. 2, a number of reaction chambers 204 (each of which can be an example of any of reaction chambers 104, 105, and/or 107 in FIG. 1) can be disposed around and/or coupled to a transfer chamber 280 comprising a transfer tool 285 for transferring substrates between reaction chambers 204. Substrates can be transferred from a load lock chamber 212 and between reaction chambers 204 (e.g., through transfer chamber 280). For example, a substrate 130 can be disposed in different chambers for different steps of a semiconductor manufacturing process (e.g., first deposition, inhibiting, etching, oxidizing, passivation and/or second deposition steps may each be performed in the same or different chambers).

FIG. 3 illustrates simplified cross-sectional schematic diagrams of semiconductor structures formed during process 300 which may be a cyclic process for selectively depositing a gap-fill material comprising second layer 330 within a gap feature 304 of a substrate 310. In an example, process 300 includes a first cyclic deposition sub-cycle to deposit a first layer 320; an etch back process to remove a portion of the first layer 320; and a second cyclic deposition sub-cycle to deposit (a second layer) second layer 330.

At operation 301, substrate 310 may be provided into a processing chamber (e.g., chamber 104 in FIG. 1). In an example, substrate 310 may have one or more gap features 304 fabricated in a top surface 312 of substrate 310.

In some examples, substrates may be patterned to include high aspect ratio features, such as, for example, vertical gap features and/or horizontal gap features. In particular examples, a patterned substrate may comprise a non-planar surface including one or more gap features (or non-linear features). For example, the term “gap feature” as used herein may refer to: an opening or cavity disposed between opposing sidewalls of two protrusions extending upwards from a surface of a substrate, or opposing sidewalls of an indentation extending downward into a surface of a substrate. Non-limiting examples of “gap features” may include, but is not limited to: trenches, vertical trenches, v-shaped trenches, tapered trenches, re-entrant trenches, openings, voids, and through-silicon-via trenches. For example, a gap feature may comprise adjacent sidewalls which meet at a point at the base of the feature, or a gap feature may comprise opposing inclined sidewalls that plateau to a flat base surface.

In some examples of the disclosure, the substrate may comprise one or more gap features, wherein the gap features may have an aspect ratio (height:width) which may be greater than 2:1, or greater than 5:1, or greater than 10:1, or greater than 25:1, or greater than 50:1, or even greater than 100:1, wherein “greater than” as used in this example refers to a greater distance in the height of the gap feature. In some examples of the disclosure, the substrate may comprise one or more horizontal gap features, wherein the horizontal gap features may have an aspect ratio (height:width) which may be greater than 1:2, or greater than 1:5, or greater than 1:10, or greater than 1:25, or greater than 1:50, or even greater than 1:100, wherein “greater than” as used in this example refers to a greater distance in the width of the gap feature. In some examples, a substrate may comprise a plurality of gap features with common and differing aspect ratios.

In an example, gap feature 304 further includes a bottom surface 318 where sidewalls 314 meet forming a lowest area 319 at the base of gap feature 304. In some examples, gap feature 304 may comprise opposing sidewalls that plateau to a flat base surface. In some examples, gap feature 304 has sidewalls 314 and/or a bottom surface 318 formed of a dielectric material (e.g., an oxide that may be represented as 1kOx). In some examples, the sidewalls 314 and/or bottom surface 318 may include dielectric materials, such as, but not limited to, silicon containing dielectric materials and metal oxide dielectric materials. In some examples, the sidewalls 314 and/or bottom surface 318 may include a silicon containing dielectric material such as, but not limited to, silicon (Si), silicon dioxide (SiO2), silicon sub-oxides, silicon nitride (Si3N4), silicon oxynitride (SiON), silicon oxycarbide (SiOC), silicon oxycarbide nitride (SiOCN), silicon carbon nitride (SiCN). In some examples, substrate 310 or at least its sidewalls 314 and/or bottom surface 318 may include one or more dielectric surfaces comprising a metal oxide such as, but not limited to, aluminum oxide (Al2O3), hafnium oxide (HfO2), tantalum oxide (Ta2O5), zirconium oxide (ZrO2), titanium oxide (TiO2), hafnium silicate (HfSiOx), and lanthanum oxide (La2O3).

At operation 303, a first layer 320 of material may be deposited by a first cyclic deposition process onto surface 312, sidewalls 314 and bottom surface 318 of substrate 310. In certain examples, first layer 320 of material may be deposited by a conformal fill process wherein the thickness of the deposited material is substantially the same on all surfaces. In certain other examples, first layer 320 of material may be deposited by a non-conformal fill process wherein the thickness of the deposited material is not substantially the same on all surfaces.

In some examples, first layer 320 may be any of a variety of materials, such as metals (e.g., molybdenum (Mo), tungsten (W), fluorine-free W (FFW), ruthenium (Ru), cobalt (Co), copper (Cu), or the like or a combination thereof), metal nitrides (e.g., titanium nitride (TiN), molybdenum nitride (MoN), tungsten nitride (WN), vanadium nitride (VN), niobium nitride (NbN), tantalum nitride (TaN), hafnium nitride (HfN), zirconium nitride (ZrN), or the like, or a combination thereof) and/or doped metal nitrides including but not limited to nitrides doped with silicon (Si), aluminum (Al), boron (B), cobalt (Co), and/or manganese (Mn), or the like or a combination thereof.

At operation 305, first layer 320 may be etched back to form a base 322. Base 322 may alternately be referred to as a plug and/or seed. Base 322 may comprise a surface 324.

In an example, halide 132 may be used at operation 305 to etch first layer 320. Such an etchant can be useful in increasing or maintaining desired selectivity and may have an added benefit of removing metal oxides from the substrate surface and/or cleaning dielectric material of residue. Exemplary halide 132 species include but are not limited to molybdenum pentachloride (MoCl5), tungsten chloride (WCl5), chlorine (C12), niobium chloride (NbCl5), titanium tetrachloride (TiCl4), vanadium tetrachloride (VCl4), tantalum pentachloride (TaCl5), hafnium tetrachloride (HfCl4), niobium fluoride (NbF5), tantalum chloride (TaCl5), or tantalum fluoride (TaF5), or the like or a combination thereof. In some examples, halide 132 may be used as a precursor for material deposition during operation 307 discussed in greater detail below. Halide 132 may be exposed to a remote, indirect, or direct plasma (e.g., remote plasma source 170 or direct plasma source 175) prior to reaching the surface of the substrate.

In an example, halide 132 may have the ability to etch a first layer 320 comprising a variety of materials such as metals (e.g., molybdenum (Mo), fluorine-free W (FFW), tungsten (W), ruthenium (Ru), cobalt (Co), copper (Cu), or the like or a combination thereof), metal nitrides (e.g., titanium nitride (TiN), molybdenum nitride (MoN), tungsten nitride (WN), vanadium nitride (VN), niobium nitride (NbN), tantalum nitride (TaN), hafnium nitride (HfN), zirconium nitride (ZrN), or the like, or a combination thereof) and/or doped metal nitrides including but not limited to nitrides doped with silicon (Si), aluminum (Al), boron (B), cobalt (Co), and/or manganese (Mn), or the like or a combination thereof.

In some examples, halide 132 etchant may have the ability to remove or etch a variety of other materials such as metals (e.g., W, Ti, Mo, Co, or Ta, or the like, or a combination thereof), oxides (e.g., Al2O3, HfO2, ZrO2, ZnO, or TiO2, or the like, or a combination thereof) and/or silicides (e.g. MoSi, TiSi, or the like, or combinations thereof). In certain examples, first layer 320 may comprise such materials.

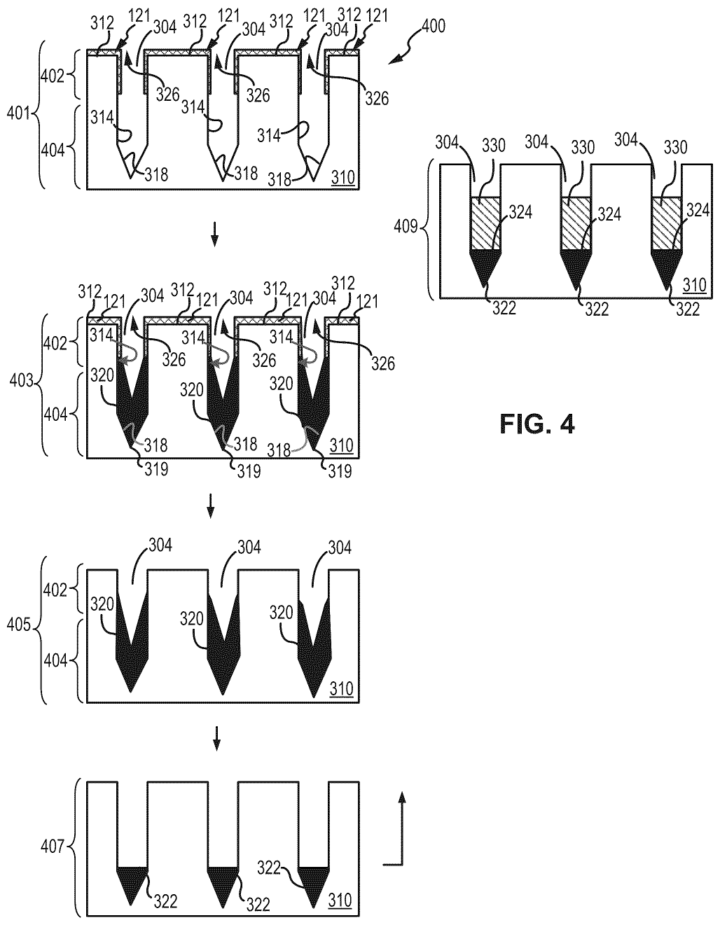

The dose of halide can be tailored to a desired etching rate in order to achieve a gradient etch of the first layer 320 wherein the top portion (e.g., see top portion 402 of feature 304 shown in FIG. 4) may be etched to a greater extent than a lower portion (e.g., lower portion 404 of feature 304 shown in FIG. 4).

At operation 307, gap feature 304 may be fully or partially filled by a second cyclic deposition process. Second cyclic deposition process may be a selective “bottom-up” fill process wherein gap feature 304 is partially or completely filled with a second layer 330. Second layer 330 may comprise a metal (or other material) selectively deposited on base 322.

In an example, process 300 may be a preferential deposition process and may entail preferentially depositing second layer 330 on base 322 of gap feature 304 on surface 324 thereby filling the vertical gap feature 304 with the gap-fill material by means of a bottom-up deposition process. Second layer 330 preferentially deposits in regions of gap feature 304 distal from openings 326 of gap features 304 at the base regions of the gap features 304 disposed distal to openings 326. In an example, second layer 330 is deposited preferentially within the base regions compared with the opening regions of the vertical gap features.

In certain examples, before bottom-up fill operation 307 for depositing a second layer 330 on first layer 320, it is typically useful to remove oxides on the substrate, and a surface cleaning step may be performed, for example, using H2-based plasma cleaning techniques in a direct plasma or a remote plasma source that are designed to remove oxides. In some examples, prior to bottom-up fill operation 307 surface 324 may be exposed to an additional etching gas 133 phase (e.g., low power NF3 plasma) to remove unwanted residues (e.g., chlorine).

Turning now to FIG. 4 illustrating a simplified cross-sectional schematic diagram of semiconductor structures formed during process 400, process 400 may be a cyclic process for selectively depositing a second layer 330 within a gap feature 304 of a substrate 310. In an example, process 400 includes a deposition operation to deposit an inhibitor 121 in a top portion 402 of gap features 304; a first cyclic deposition sub-cycle to deposit a first layer 320; an etch back process to remove a portion of the first layer 320; and a second cyclic deposition sub-cycle to deposit (a second layer) second layer 330.

At operation 401, substrate 310 may be provided into a processing chamber (e.g., chamber 104 in FIG. 1). In an example, substrate 310 may have one or more gap features 304 fabricated in a top surface 312 of substrate 310. In an example, substrate 310 may be exposed to an inhibitor 121 to inhibit deposition of first layer 320 on top surface 312 and sidewalls 314 in top portion 402 of substrate 310. In an example, gap feature 304 further includes a bottom surface 318 where sidewalls 314 meet forming a lowest area 319 at the base of gap feature 304.

In an example, inhibitor 121 may be selected to preferentially deposit on top surface 312 and sidewalls 314 in top portion 402 of substrate 310 so as to prevent first layer 320 from forming on sidewalls 314 in top portion 402 to a greater extent than lower portion 404 of substrate within gap feature 304 in operation 403. Reduction in deposition at the opening of gap feature 304 may improve throughput by reducing time to perform etch back after deposition of first layer 320.

At operation 403, a first layer 320 of material may be deposited by a first cyclic deposition process in gap feature 304 onto sidewalls 314 and bottom surface 318 of gap feature 304. In certain examples, first layer 320 of material may be deposited by a non-conformal fill process wherein the thickness of the deposited material is not the same on all surfaces. For example, first layer 320 may be deposited to a greater thickness on surfaces of sidewall 314 and bottom surface 318 in lower portion 404 than on surfaces within top portion 402. Thus, the deposited film of first layer 320 may not have a substantially uniform thickness across the surfaces of substrate 310. Rather, inhibitor 121 may be used to preferentially suppress deposition in top portion 402 of gap feature 304 thereby resulting a non-conformal deposition. Therefore, inhibitor 121 may cause preferential deposition of first layer 320 in lower portion 404 of gap feature 340 at a distal location from opening 326. In some examples, the non-conformal deposition process may preferentially deposit a metal nitride film in gap feature 304.

Inhibitor 121 may comprise any of a variety of passivating species such as a silane, such as an alkylaminosilane. In some examples, inhibitor 121 may comprise allyltrimethylsilane (TMS-A), chlorotrimethylsilane (TMS-Cl), N-(trimethylsilyl)imidazole (TMS-Im), octadecyltrichlorosilane (ODTCS), hexamethyldisilazane (HMDS), N-(trimethylsilyl) dimethylamine (TMSDMA) or trimethylchlorosilane, or the like or a combination thereof.

At operation 405, inhibitor 121 is removed leaving first layer 320 in lower portion 404 of gap feature 340. Inhibitor 121 may be removed from surface 312 and/or sidewalls 314 by a variety of methods known to those of skill in the art.

In some examples, the method for removing inhibitor 121 includes exposing the substrate to an etchant, plasma and/or cleaning agent or process. In some examples, removing inhibitor 121 includes hydrogen plasma treatment. In some examples, cleaning or removing inhibitor 121 includes baking substrate 310 to a temperature of about 300° C. to 400° C., or any appropriate temperature.

At operation 407, first layer 320 material may be etched back to form a base 322. The etching operation 407 may be the same or similar as described with reference to FIG. 3 operation 305.

In some examples, interface voids between first layer 320 and second layer 330 may form, especially after downstream substrate treatments involving annealing. These voids may negatively impact the electrical performance of a device incorporating substrate 310, but also suggests a non-negligible level of impurities in the first layer 320 (e.g., thin film). Impurities are undesirable because they cause issues in the following process flow. To address this problem, an added etch step may remove residues (e.g., Cl-related) that may tend to accumulate in features 304 and are difficult to remove. These residues may become trapped after second layer 330 deposition (e.g., with Mo) on a surface 324 of base 322. Such residues may evaporate or sublimate during subsequent annealing steps, creating voids in the film.

In an example, etched first layer 320 may be exposed to an additional etching gas 133 (e.g., NF3) activated by a low power plasma for a short period (e.g., one to several seconds) after thermal etch back in operation 407. By adjusting the etching gas flow, the plasma power can be controlled and so too can the resulting etch rate. By optimizing the timing of the etching gas plasma treatment, it may be possible to significantly minimize the formation of interface voids.

The etching gas may include a fluorine-containing gas, for example, nitrogen trifluoride (NF3). The fluorine-containing gas may be activated in-situ and/or by remotely supplied RF power, and impurities residing on first layer 320 may be removed. The low power plasma may be in the range of about 50-400 watts, or any appropriate power. This in-situ process reduces or eliminates the need for additional tools and simplifies the process flow, and may result in shorter device production turnaround times, enhanced yields, and reduced costs.

At operation 409, gap feature 304 may be fully or partially filled by a second cyclic deposition process. Second cyclic deposition process may be a selective “bottom-up” fill process that is the same or similar to that described with respect to FIG. 3 at operation 307, wherein gap feature 304 is partially or completely filled with a second layer 330.

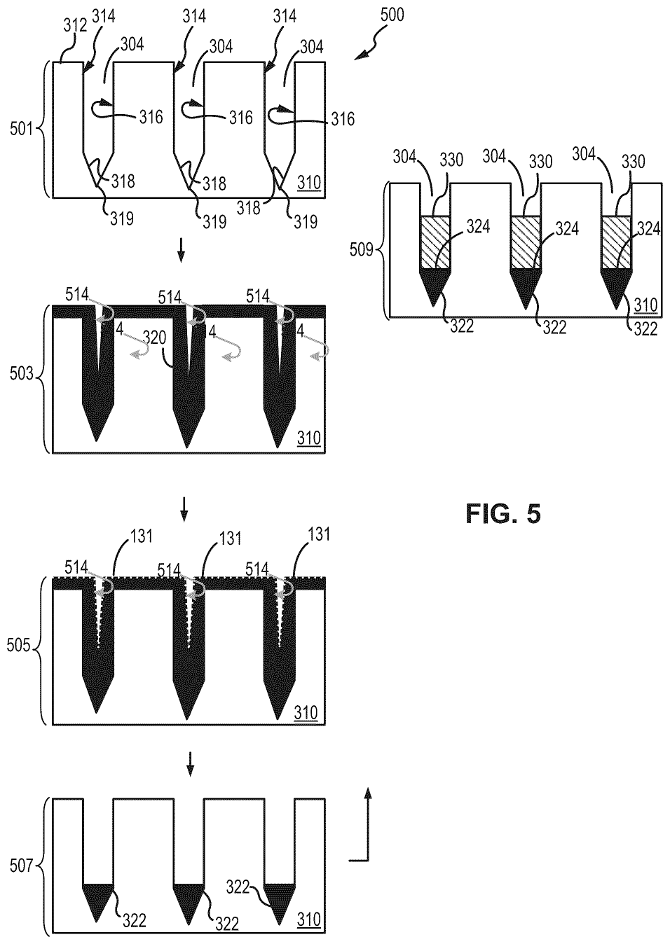

FIG. 5 illustrates simplified cross-sectional schematic diagrams of semiconductor structures formed during process 500 which may be a cyclic process for selectively depositing a second layer 330 within a gap feature 304 of a substrate 310. In an example, process 500 includes a first cyclic deposition sub-cycle to deposit a first layer 320; oxidation of at least a surface portion of first layer 320; an etch back process to remove a portion of the first layer 320; and a second cyclic deposition sub-cycle to deposit (a second layer) second layer 330.

At operation 501, substrate 310 may be provided into a processing chamber (e.g., chamber 104 in FIG. 1). In an example, substrate 310 may have one or more gap features 304 fabricated in a top surface 312 of substrate 310. In an example, gap feature 304 further includes a bottom surface 318 where sidewalls 314 meet forming a lowest point 319 at the base of gap feature 304.

At operation 503, a first layer 320 of material may be deposited by a first cyclic deposition process in gap feature 304 onto sidewalls 314 and bottom surface 318 of gap feature 304. In certain examples, first layer 320 of material may be deposited by a conformal fill process wherein the thickness of the deposited material is substantially the same on all surfaces. In other examples, first layer 320 of material may be deposited by a non-conformal fill process wherein the thickness of the deposited material is not substantially the same on all surfaces, for example, where an inhibitor 121 is applied (see for example operation 403 shown in FIG. 4). In an example, first layer 320 may have an exposed surface 514.

At operation 505, exposed surface 514 of first layer 320 maybe oxidized by Oxidizer 131 contacting surface 514. Oxidizer 131 may comprise any of a variety of oxidizers including water (H2O), hydrogen peroxide (H2O2), ozone (O3), oxygen (O2), O2 plasma, alcohol, alkyl alcohol, ethanol, methanol, butanol, isobutanol, isopropanol, or the like or combinations thereof. Oxidizer 131 may be a vapor operation reactant pulsed into chamber 104 or may be a plasma generated by a remote or direct plasma source. In an example, oxidizing surface 514 may improve an etch rate at operation 507.

At operation 507, first layer 320 material may be etched back to form a base 322. The etching operation 407 may be the same or similar as described with reference to FIG. 3 operation 305.

As previously discussed with reference to FIG. 4, in some examples, interface voids between first layer 320 and second layer 330 may form due to accumulation of impurities such as halides (e.g., Cl) and downstream annealing steps that cause trapped impurities to evaporate and/or sublimate during subsequent annealing steps, creating voids in the film. To address this issue, etched first layer 320 may be exposed to low power plasma etch for a predetermined time (for example, one to a few seconds) after thermal etch back in operation 507.

At operation 509, gap feature 304 may be fully or partially filled by a second cyclic deposition process. Second cyclic deposition process may be a selective “bottom-up” fill process that is the same or similar to that described with respect to FIG. 3 at operation 307, wherein gap feature 304 is partially or completely filled with a second layer 330.

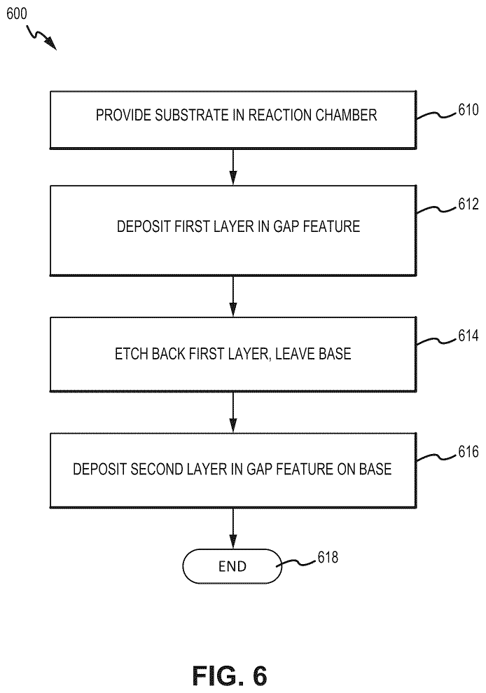

FIG. 6 illustrates a cyclic deposition process 600 for filling one or more gap features 304 on a substrate 310 according to various examples of the disclosure. In particular, process 600 may commence by means of a process block 610 which comprises, providing a substrate (e.g., substrate 310 shown in FIG. 3) comprising a gap feature (e.g., gap feature 304 shown in FIG. 3) into a reaction chamber (e.g., chamber 104 shown in FIG. 1) and heating the substrate to a desired deposition temperature.

In an example, substrate 310 may comprise one or more materials and material surfaces including, but not limited to, semiconductor materials, dielectric materials, and metallic materials.

In some examples, the substrate may include semiconductor materials, such as, but not limited to, silicon (Si), germanium (Ge), germanium tin (GeSn), silicon germanium (SiGe), silicon germanium tin (SiGeSn), silicon carbide (SiC), or a group III-V semiconductor materials.

In some examples, the substrate may include metallic materials, such as, but not limited to, pure metals, metal nitrides, metal carbides, metal borides, and mixtures thereof.

In some examples, the substrate may include dielectric materials, such as, but not limited to silicon containing dielectric materials and metal oxide dielectric materials. In some examples, the substrate may comprise one or more dielectric surfaces comprising a silicon containing dielectric material such as, but not limited to, silicon dioxide (SiO2), silicon sub-oxides, silicon nitride (Si3N4), silicon oxynitride (SiON), silicon oxycarbide (SiOC), silicon oxycarbide nitride (SiOCN), silicon carbon nitride (SiCN). In some examples, the substrate may comprise one or more dielectric surfaces comprising a metal oxide such as, but not limited to, aluminum oxide (Al₂O₃), hafnium oxide (HfO2), tantalum oxide (Ta2O5), zirconium oxide (ZrO2), titanium oxide (TiO2), hafnium silicate (HfSiOx), and lanthanum oxide (La2O3), or the like or combinations thereof.

Substrate 310 may be patterned. Patterned substrates may comprise substrates that may include semiconductor device structures formed into or onto a surface of the substrate, for example, a patterned substrate may comprise partially fabricated semiconductor device structures, such as, for example, transistors and/or memory elements. In some examples, the substrate may contain monocrystalline surfaces and/or one or more secondary surfaces that may comprise a non-monocrystalline surface, such as a polycrystalline surface and/or an amorphous surface. Monocrystalline surfaces may comprise, for example, one or more of silicon (Si), silicon germanium (SiGe), germanium tin (GeSn), or germanium (Ge). Polycrystalline or amorphous surfaces may include dielectric materials, such as oxides, oxynitrides, oxycarbides, oxycarbide nitrides, nitrides, or mixtures thereof.

Once the substrate is disposed within a suitable reaction chamber, such as, for example, an atomic layer deposition reaction chamber or a chemical vapor deposition reaction chamber, the substrate may be heated to a desired deposition temperature. In some examples, the exemplary cyclic deposition process 600 (FIG. 6) may be performed at a constant deposition temperature, i.e., substrate temperature. In alternative examples, the substrate may be heated to a first substrate temperature for contacting the substrate with the deposition precursors (e.g., a metal precursor and a nitrogen precursor) and the substrate may be heated to a second substrate temperature, different from the first substrate temperature, for contacting the substrate with the halide etchant.

In some examples of the disclosure, the substrate may be heated to a deposition temperature (i.e., substrate temperature) of less than 600° C., or less than 550° C., or less than 500° C., or less than 450° C., or less than 400° C. or less than 300° C. In some examples, the substrate may be heated to a deposition temperature between 200° C. and 600° C., or between 300° C. and 575° C., or between 400° C. and 550° C., or between 425° C. and 500° C.

In addition, to achieving a desired deposition temperature, the exemplary cyclic deposition process 600 may also regulate the pressure within the reaction chamber. For example, in some examples of the disclosure, the reaction chamber pressure may be regulated to less than 300 Torr, or less than 200 Torr, or less than 100 Torr, or less than 50 Torr, or less than 25 Torr, or less than 10 Torr, or less than 5 Torr, or less than 3 Torr, or even less than 1 Torr. In some examples, the reaction chamber pressure may be regulated at a pressure between. 5 Torr and 300 Torr, or between 1 Torr and 10 Torr, or between 1 Torr and 5 Torr, or between 1 Torr and 3 Torr.

In an example, a first layer (e.g., first layer 320 shown in FIG. 3) may be deposited within a gap feature (e.g., gap feature 304 shown in FIG. 3) of the substrate at process block 612. As described above, first layer 320 make comprise any of a variety of materials that may be deposited into gap feature 304 by a variety of deposition methods and claimed subject matter is not limited in this regard. Process block 612 may comprise one or more deposition sub-cycles that may be repeated until first layer 320 reaches a predetermined thickness.

In an example, at process block 614, the first layer (e.g., first layer 320 shown in FIG. 3) may be etched back to a base (e.g., base 322 shown in FIG. 3). As described above, etching may be performed by any of a variety of materials, for example, those discussed above with respect to at operation 305 in FIG. 3. Process block 614 may comprise one or more etching sub-cycles that may be repeated until base 322 is etched to a predetermined thickness.

In an example, a second layer (e.g., second layer 330 shown in FIG. 3) may be deposited within a gap feature (e.g., gap feature 304 shown in FIG. 3) of the substrate at process block 616. As described above, second layer 330 make comprise any of a variety of materials that may be deposited into gap feature 304 by a variety of deposition methods and claimed subject matter is not limited in this regard. Process block 616 may comprise one or more deposition sub-cycles that may be repeated until second layer 330 reaches a predetermined thickness. At block 618, process 600 may end.

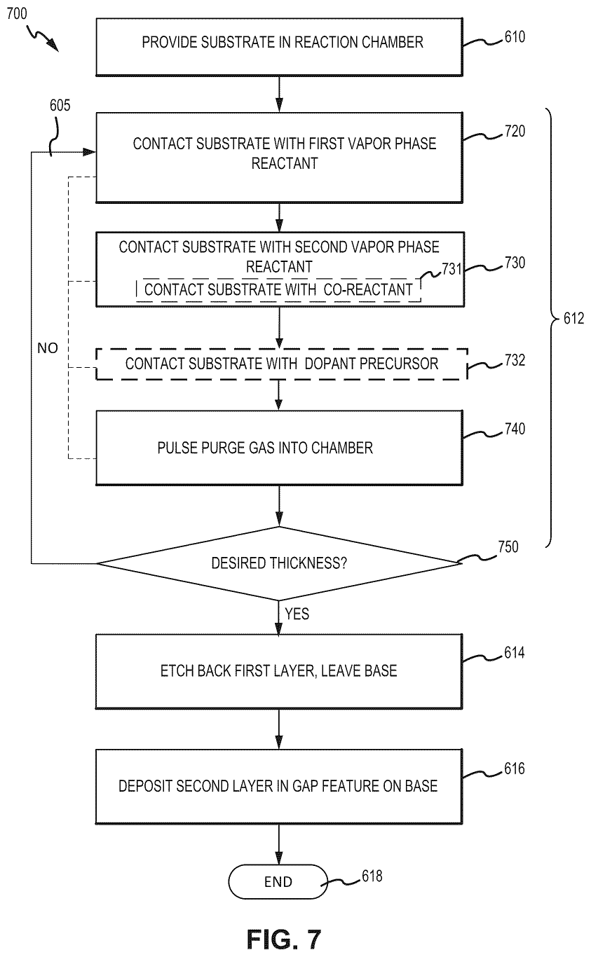

FIG. 7 illustrates an example of a cyclic deposition process 700 for partially or completely filling one or more gap features on a substrate according to various examples of the disclosure.

Process 700 may begin with process block 610 where a substrate (e.g., substrate 310 shown in FIG. 3) comprising a gap feature (e.g., gap feature 304 of FIG. 3) is supported in a reaction chamber (e.g., chamber 104 shown in FIG. 1).

In an example, a first layer (e.g., first layer 320 shown in FIG. 3) may be deposited within a gap feature (e.g., gap feature 304 of FIG. 3) of the substrate by cyclic deposition sub-cycle 612 (expanding block 612 from FIG. 6).

In an example, first layer 320 may be any of a variety of materials, such as metals (e.g., molybdenum (Mo), tungsten (W), fluorine-free W (FFW), ruthenium (Ru), cobalt (Co), copper (Cu), or the like or a combination thereof), metal nitrides (e.g., titanium nitride (TiN), molybdenum nitride (MoN), tungsten nitride (WN), vanadium nitride (VN), niobium nitride (NbN), tantalum nitride (TaN), hafnium nitride (HfN), zirconium nitride (ZrN), or the like, or a combination thereof) and/or doped metal nitrides including but not limited to nitrides doped with silicon (Si), aluminum (Al), boron (B), cobalt (Co), and/or manganese (Mn), or the like or a combination thereof.

In some examples of the disclosure, first layer 320 may comprise metallic ternary film, such as, for example, a ternary metal nitride film, a ternary metal oxide film, a ternary metal carbide film, a ternary metal silicide film, a ternary metal sulfide film, a ternary metal selenide film, a ternary metal phosphide film, a ternary metal boride film, or mixtures and/or laminates thereof. In some examples, the ternary first layer may comprise: titanium aluminum nitride (TiAlN), titanium aluminum carbide (TiAlC), titanium niobium nitride (TiNbN), or titanium silicon nitride (TiSiN).

In an example, cyclic deposition sub-cycle 612 may begin at process block 720 where the substrate may be contacted with a first vapor phase precursor (e.g., first vapor phase precursor 115 shown in FIG. 1), process block 730 where the substrate is contacted with a second vapor phase precursor (e.g., second vapor phase precursor 117 shown in FIG. 1), process block 740 where the reaction chamber may be purged (e.g., purge gas 124 shown in FIG. 1), and/or process block 750 where the sub-cycle may repeat if the first layer has not reached a predetermined thickness. Alternatively, if the first layer has reached a predetermined thickness cyclic deposition sub-cycle 612 may end and process 700 may proceed to another processing phase (e.g., etch back at block 614).

In particular, at process block 720, a first vapor phase precursor may contact substrate 310. First vapor phase precursor may comprise a metal precursor and/or a metallic precursor. In some examples, the first vapor phase precursor may comprise a metal halide precursor, such as, for example, a metal chloride precursor, a metal iodide precursor, or a metal bromide precursor. In particular examples, the metal halide precursor may comprise: titanium tetrachloride (TiCl4), titanium tetraiodide (TiI4), titanium tetrabromide (TiBr3), hafnium tetrachloride (HfCl4), boron trichloride (BCl3), aluminum trichloride (AlCl3), silicon tetrachloride (SiCl4), disilicon hexachloride (Si2Cl6), 2-methylcyclohexa-2,5-diene-1,4-diyl)bis(trimethylsilane) (C13H26Si2), triethyl borate (B(OCH2CH3)3), trisilicon octochloride (Si3C18), dichlorosilane (SiH2C12), NiCl2 (TMPDA), gallium monochloride (GaCl), gallium trichloride (GaCl3), niobium pentachloride (NbCl5), molybdenum tetrachloride (MoCl4), molybdenum pentachloride (MoCl5), molybdenum (V) trichloride oxide (MoOCl3), molybdenum (VI) tetrachloride oxide (MoOCl4), molybdenum (IV) dichloride dioxide (MoO2Cl2), indium trichloride (InCl3), tantalum pentachloride (TaCl5), tungsten hexachloride (WCl6), vanadium fluoride (VF3), vanadium chloride (VCl3), vanadium oxychloride (VOCl3), and/or zirconium tetrachloride (ZrCl4), or the like or combinations thereof.

In some examples of the disclosure, contacting the substrate with a metal precursor may comprise contacting the substrate with the metal precursor for a time period of between about 0.01 seconds and about 60 seconds, or between about 0.05 seconds and about 10 seconds, or between about 0.1 seconds and about 5.0 seconds, or even between 0.2 seconds and 1 second, or any appropriate time period.

The cyclic deposition sub-cycle 612 may continue by purging the reaction chamber at block 740. For example, excess metal precursor may be removed from the surface of the substrate by introducing an inert purge gas 124 (e.g., Ar) and exhausting the reaction chamber with the aid of a vacuum pump in fluid communication with the reaction chamber. The purge process may comprise a purge cycle, wherein the substrate surface is purged for a time period of less than 5 seconds, or less than 3 seconds, or less than 2 seconds, or even less than 1 second, or any appropriate amount of time. In some examples, the substrate surface is purged for a time period between 0.1 seconds and 5 seconds.

The cyclic deposition sub-cycle 612 may continue to block 730 where the substrate is contacted with a second vapor phase precursor. In an example, second vapor phase precursor may comprise a nitrogen precursor.

In some examples of the disclosure, the nitrogen precursor may comprise: molecular nitrogen (N2), ammonia (NH3), hydrazine (N2H4), a hydrazine derivative, or a nitrogen-based plasma. In some examples, the hydrazine derivative may comprise an alkyl-hydrazine including at least one of: tertbutylhydrazine (C4H9N2H3), methylhydrazine (CH3NHNH2), or dimethylhydrazine ((CH3)2N2H2). In some examples, the nitrogen-based plasma may be generated by the application of RF power to a nitrogen containing gas and the nitrogen-based plasma may comprise atomic nitrogen (N), nitrogen ions, nitrogen radicals, and excited species of nitrogen. In some examples, the nitrogen-based plasma may further comprise additional reactive species, such as, by the addition of a further gas.

Optionally, before, simultaneously with and/or subsequent to operation block 730, process 700 may include an operation at block 731 of contacting substrate 310 with a precursor 134 (e.g., H2). Accordingly a pulse sequence may comprise, for example, one or more pulses with a first vapor phase precursor (e.g., TiCl4) at block 720, followed by a purge (e.g., Ar purge gas 124) at block 740, then precursor 134 (e.g., H2) and the second vapor phase precursor 117 (e.g., NH3) may be pulsed simultaneously at blocks 730 and 731, followed by a pulse of precursor 134 (e.g., H2) alone, repeating the operation at block 731, followed again by a purge (e.g., Ar purge gas 124) at block 740.

In an example, cyclic deposition sub-cycle 612 may continue from block 730 or 731 by purging the reaction chamber at block 740.

Optionally, cyclic deposition sub-cycle 612 may proceed to block 732 where the substrate may be contacted with a dopant-containing precursor. The dopant-containing precursor may be introduced into the chamber before, during, or after contact the substrate with second vapor phase precursor 117 at block 730. By introduction of the dopant-containing precursor, the cyclic deposition sub-cycle 612 may deposit a doped nitride layer into the gap feature comprising any of a variety of dopants including but not limited to Si, Al, B, Co, or Mn, or combinations thereof.

In some examples, a metalorganic precursor may be utilized to provide a carbon component to the first layer and/or an additional metal component thereby depositing a ternary or quaternary first layer.

In some examples, a silicon precursor may be utilized to provide a Si component such as, for example: silane (SiH4), disilane (Si2H6), trisilane, (Si3H8), tetrasilane (Si4H10), isopentasilane (Si5H12), or neopentasilane (Si5H12). In some examples, the silicon precursor may comprise a C1-C4 alkylsilane.

In some examples of the disclosure, the first layer may comprise at least one of a: metal nitride film, doped nitride film, metal oxide film, metal carbide film, metal silicide film, metal sulfide film, metal selenide film, metal phosphide film, metal boride film, or mixtures and/or laminates thereof. In particular examples, the first layer may comprise at least one of a: transition metal oxide film, transition metal nitride film, transition metal silicide film, transition metal phosphide film, transition metal selenide film, transition metal boride film, or mixtures and/or laminates thereof.

In some examples of the disclosure, the first layer may comprise a titanium nitride film.

Upon contacting the substrate with the second vapor phase precursor, cyclic deposition sub-cycle 612 of exemplary cyclic deposition process 700 may proceed to a reaction chamber purging operation at block 740 (e.g., pulsing purge gas into the chamber), as indicated by dashed lines, purging operation 740 may optionally be executed at any juncture in cyclic deposition sub-cycle 612 (e.g., before, after and/or between operations in at least blocks 720, 730, 731 and/or 732).

At block 750, if the desired (i.e., predetermined) thickness of the first layer has not been achieved then cyclic deposition sub-cycle 612 may be repeated any number of times (see arrow 605 returning to block 720) appropriate to increase the thickness of the first layer to the desired thickness. Arrow 605 may return to any of blocks 720, 730, 731 and/or 732 of cyclic deposition sub-cycle 612 to repeat operations of cyclic deposition sub-cycle 612. Moreover, operations at blocks 720, 730, 731, 732 and/or 740 of cyclic deposition sub-cycle 612 may be carried out in any order, be skipped, repeated, and/or be separated by one or more purge operations at block 740, and claimed subject matter is not limited in this regard.

In some examples of the disclosure, the first layer may be deposited to an average film thickness of between 3 Å and 30 Å or any appropriate thickness. In some examples, the first layer comprises a titanium nitride film deposited to an average film thickness of between 3 Å and 30 Å.

In some examples of the disclosure, the first layer 320 may be physically continuous at an average film thickness of more than 10 Å. In some examples, the first layer 320 comprises a film which may be physically continuous at an average film thickness of less than 10 Å.

Upon reaching the desired thickness of first layer, process 700 may proceed to block 614, where the first layer (e.g., first layer 320 shown in FIG. 3) may be etched back to a base (e.g., base 322 shown in FIG. 3). Process block 614 may comprise one or more etching sub-cycles that may be repeated until base 322 is etched to a predetermined thickness.

Upon reaching the desired thickness of the etched first layer (base 322), process 700 may proceed to block 616 where a second layer (e.g., second layer 330 in FIG. 3) may be deposited in the gap feature (e.g., gap feature 304 shown in FIG. 3) of the substrate. Process block 616 may comprise one or more deposition sub-cycles that may be repeated until second layer 330 reaches a predetermined thickness. At block 618, process 700 may end.

In some examples, during processing, the temperature of the reaction chamber during cyclic deposition sub-cycle 612 may be less than about 600° C., less than about 550° C., less than about 500° C., less than about 450° C., or less than about 400° C., or any appropriate temperature. The pressure of the reaction chamber during operation 303 may be between 0.1 and 10 Torr, or between 1 and 5 Torr, or between 1 and 3 Torr, or any appropriate pressure. In an example, at operation 303 a reactant source vessel (e.g., reactant source vessel 110 and/or 112) temperature may be less than about 70° C., less than about 60° C., less than about 50° C., less than about 40° C., or less than about 35° C. or between about 30-40° C., or any appropriate temperature.

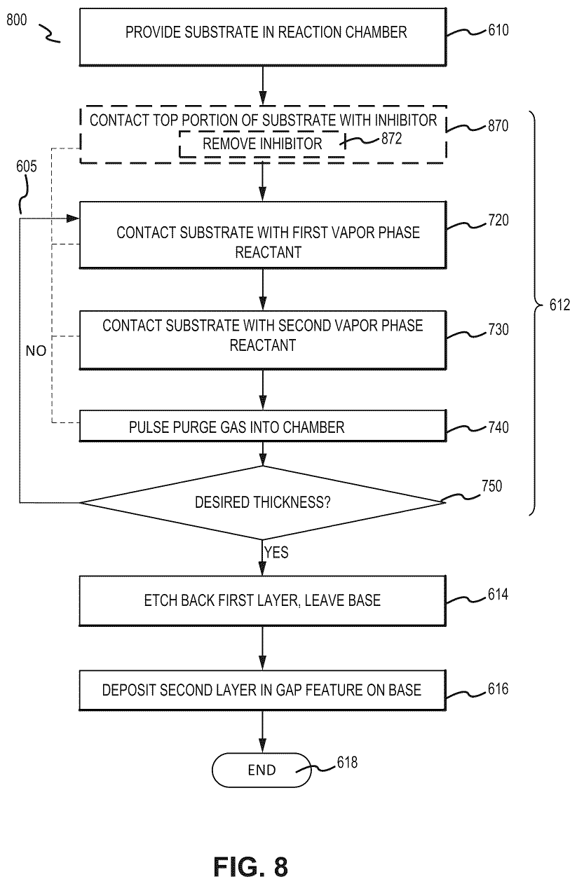

FIG. 8 illustrates an example of a cyclic deposition process 800 for partially or completely filling one or more gap features on a substrate according to various examples of the disclosure. Process 800 is similar to process 700 described with reference to FIG. 7, however, process 800 includes optional treatment of a top portion of the gap feature with an inhibitor (e.g., inhibitor 121).

For example, process 800 may begin with process block 610 where a substrate (e.g., substrate 310 shown in FIG. 4) comprising a gap feature (e.g., gap feature 304 of FIG. 4) is supported in a reaction chamber (e.g., chamber 104 shown in FIG. 1). First layer (e.g., first layer 320 shown in FIG. 4) may be deposited within a gap feature (e.g., gap feature 304 of FIG. 4) of the substrate by cyclic deposition sub-cycle 612.

In a particular example, cyclic deposition sub-cycle 612 may include an optional operation at process block 870 comprising contacting a top portion (e.g., top portion 402 shown in FIG. 4) of the substrate with an inhibitor (e.g., inhibitor 121 shown in FIG. 1). As described above, an inhibitor may inhibit deposition of first layer 320 in various areas where the inhibitor is deposited such as in the top portion of the substrate (e.g., top surface 312 and sidewalls 314 shown in FIG. 4).

Inhibitor 121 may be used to preferentially suppress deposition of first layer 320 in top portion 402 of gap feature 304 thereby resulting a non-conformal deposition. Inhibitor 121 may cause preferential deposition of first layer 320 in lower portion 404 of gap feature 340 at a distal location from opening 326. In some examples, the non-conformal deposition process may preferentially deposit a metal nitride film in gap feature 304.

Cyclic deposition sub-cycle 612 process may continue (as described above with respect to FIG. 7) to block 720 where the substrate is contacted with a first vapor phase precursor (e.g., first vapor phase precursor 115 shown in FIG. 1), process block 730 where the substrate is contacted with a second vapor phase precursor (e.g., second vapor phase precursor 117 shown in FIG. 1), process block 740 where the reaction chamber may be purged (e.g., purge gas 124 shown in FIG. 1), and/or process block 750 where the sub-cycle may repeat if the first layer has not reached a predetermined thickness. Alternatively, if the first layer has reached a predetermined thickness cyclic deposition sub-cycle 612 may end and process 800 may proceed to another processing phase (e.g., etch back at block 714).

At optional block 872, the inhibitor may be removed leaving first layer in lower portion 404 of gap feature 340. Inhibitor 121 may be removed from surface 312 and/or sidewalls 314 by any of a variety of methods known to those of skill in the art.

Upon reaching the desired thickness of first layer, process 800 may proceed to block 614, where the first layer (e.g., first layer 320 shown in FIG. 3) may be etched back to a base (e.g., base 322 shown in FIG. 3). Process block 614 may comprise one or more etching sub-cycles that may be repeated until base 322 is etched to a predetermined thickness.

At block 750, if the desired (i.e., predetermined) thickness of the first layer has not been achieved then cyclic deposition sub-cycle 612 may be repeated any number of times (see arrow 605 returning to block 720) appropriate to increase the thickness of the first layer to the desired thickness. Arrow 605 may return to any of blocks 870, 720, 730, 731 and/or 732 of cyclic deposition sub-cycle 612 to repeat operations of cyclic deposition sub-cycle 612. Moreover, operations at blocks 870, 872, 720, 730, 731, 732 and/or 740 of cyclic deposition sub-cycle 612 may be carried out in any order, be skipped, repeated, and/or be separated by one or more purge operations at block 740, and claimed subject matter is not limited in this regard.

Upon reaching the desired thickness of the etched first layer (base 322), process 800 may proceed to block 616 where a second layer (e.g., second layer 330 in FIG. 3) may be deposited in the gap feature (e.g., gap feature 304 shown in FIG. 3) of the substrate. Process block 616 may comprise one or more deposition sub-cycles that may be repeated until second layer 330 reaches a predetermined thickness. At block 618, process 800 may end.

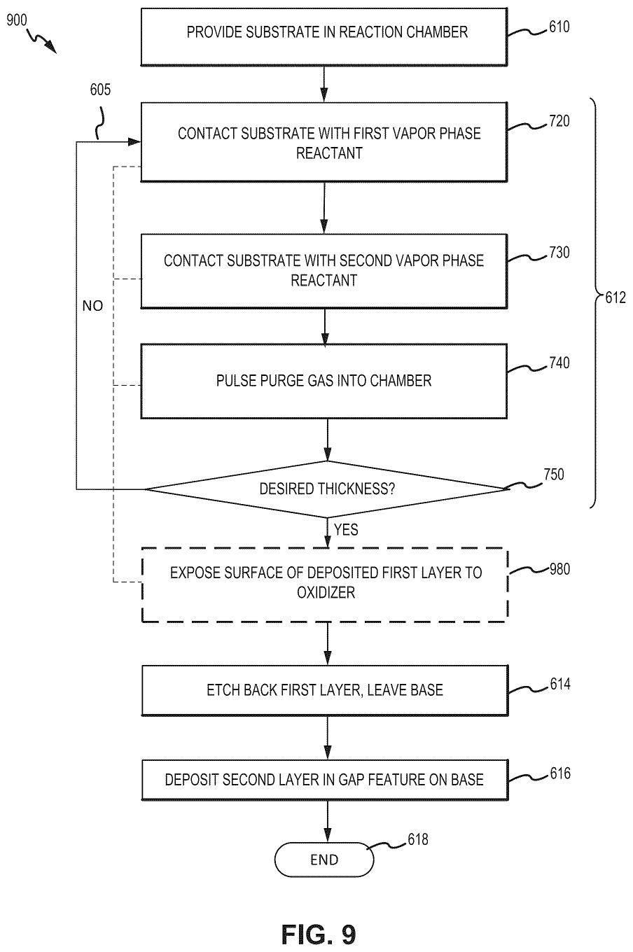

FIG. 9 illustrates an example of a cyclic deposition process 900 for partially or completely filling one or more gap features on a substrate according to various examples of the disclosure. Process 900 is similar to process 700 described with reference to FIG. 7, however, process 900 includes optional oxidation of an exposed surface of a deposited first layer.

For example, process 900 may begin with process block 610 where a substrate (e.g., substrate 310 shown in FIG. 5) comprising a gap feature (e.g., gap feature 304 of FIG. 5) is supported in a reaction chamber (e.g., chamber 104 shown in FIG. 1). First layer (e.g., first layer 320 shown in FIG. 5) may be deposited within a gap feature (e.g., gap feature 304 of FIG. 5) of the substrate by cyclic deposition sub-cycle 612.

Cyclic deposition sub-cycle 612 process may proceed to block 720 where the substrate is contacted with a first vapor phase precursor (e.g., first vapor phase precursor 115 shown in FIG. 1), process block 730 where the substrate is contacted with a second vapor phase precursor (e.g., second vapor phase precursor 117 shown in FIG. 1), process block 740 where the reaction chamber may be purged (e.g., purge gas 124 shown in FIG. 1), and/or process block 750 where sub-cycle 612 may repeat if the first layer 320 has not reached a predetermined thickness. If first layer has reached a predetermined thickness, cyclic deposition sub-cycle 612 may end and process 900 may proceed to another processing phase (e.g., oxidizing at block 980).

In a particular example, cyclic deposition sub-cycle 612 may move to process block 980 comprising oxidizing an exposed surface (e.g., exposed surface 514 as shown in FIG. 5) of first layer 320. Oxidizing exposed surface 514 may be executed by a variety of processes including contacting exposed surface 514 with an oxidizing species (e.g., oxidizer 131 shown in FIG. 1). As described with respect to FIG. 5, the oxidizer may comprise water (H2O), hydrogen peroxide (H2O2), ozone (O3), oxygen (O2), O2 plasma, alcohol, alkyl alcohol, ethanol, methanol, butanol, isobutanol, isopropanol, or the like or combinations thereof. Oxidizer 131 may be a vapor operation reactant pulsed into chamber 104 or may be a plasma generated by a remote or direct plasma unit.

Operations at blocks 720, 730, 740 and/or 980 may be carried out in any order, be skipped, repeated, and/or be separated by one or more purge operations at block 740, and claimed subject matter is not limited in this regard.

In an example, oxidizing surface 514 may improve an etch rate operation at block 614 where the first layer may be etched back to a base 322. Process block 614 may comprise one or more etching sub-cycles that may be repeated until base 322 is etched to a predetermined thickness.

Upon reaching the desired thickness of the etched first layer (base 322), process 900 may proceed to block 616 where a second layer may be deposited in the gap feature (e.g., gap feature 304 shown in FIG. 3) of the substrate. Process block 616 may comprise one or more deposition sub-cycles that may be repeated until second layer 330 reaches a predetermined thickness. At block 618, process 900 may end.

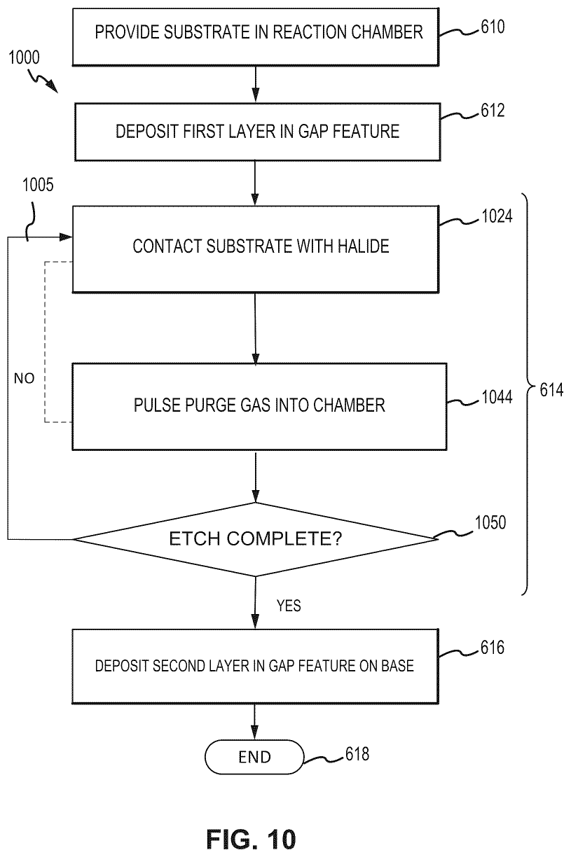

FIG. 10 illustrates an example of a cyclic deposition process 1000 for partially or completely filling one or more gap features on a substrate according to various examples of the disclosure.

In an example, process 1000 may begin with process block 610 where a substrate (e.g., substrate 310 shown in FIG. 3) comprising a gap feature (e.g., gap feature 304 of FIG. 3) is supported in a reaction chamber (e.g., chamber 104 shown in FIG. 1). First layer (e.g., first layer 320 shown in FIG. 3) may be deposited to a desired thickness within a gap feature (e.g., gap feature 304 of FIG. 3) of the substrate by a cyclic deposition sub-cycle represented in block 612 and described above, at least, with reference to FIGS. 7-9.

In a particular example, process 1000 may proceed to a cyclic etching sub-cycle 614 (expanding block 614 from FIG. 6), which may be repeated to etch back first layer 320 to form a base (e.g., base 322 shown in FIG. 3). Base 322 may comprise a surface (e.g., surface 324 shown in FIG. 3). Cyclic etching sub-cycle 614 may be repeated until base 322 is etched to a predetermined thickness. In an example, cyclic etching sub-cycle 614 may comprise a thermal atomic layer etching step. In some examples, the etching may be performed on a variety of materials forming first layer 320 described herein including metal nitride film such as TiN.

In an example, cyclic etching sub-cycle 614 may start at block 1024 where the substrate may be contacted with a halide (e.g., halide 132 in FIG. 1). Such an etchant can be useful in increasing or maintaining desired selectivity and has an added benefit of removing metal oxides from the substrate surface and/or cleaning dielectric material of residue. Exemplary etchants may include NF3, molybdenum pentachloride (MoCl5) and/or other metal halides, such as tungsten chloride (WCl5), chlorine (C12), niobium chloride (NbCl5), titanium tetrachloride (TiCl4), vanadium tetrachloride (VCl4), tantalum pentachloride (TaCl5), hafnium tetrachloride (HfCl4), niobium fluoride (NbF5), tantalum chloride (TaCl5), or tantalum fluoride (TaF5), or the like or a combination thereof.

In an example, a concentration of halide 132 may impact etching activity. In an example, reactant vessel 140 temperature may be maintained at about 100° C. to 150° C. to maintain a faster or desired etch rate. In an example, a higher reactant vessel 140 temperature provides higher dose of halide 132. In certain examples, halide 132 may be exposed to a remote, indirect, or direct plasma prior to reaching the surface of the substrate.

In an example, the etchant may have the ability to etch a first layer 320 comprising a variety of materials such as metals including but not limited to molybdenum (Mo), tungsten (W), ruthenium (Ru), cobalt (Co), copper (Cu), or the like or a combination thereof; metal nitrides including but not limited to titanium nitride (TiN), molybdenum nitride (MON), tungsten nitride (WN), vanadium nitride (VN), niobium nitride (NbN), tantalum nitride (TaN), hafnium nitride (HfN), zirconium nitride (ZrN), or the like, or a combination thereof; and/or doped metal nitrides including but not limited to nitrides doped with silicon (Si), aluminum (Al), boron (B), cobalt (Co), or manganese (Mn), or the like or a combination thereof.

In some examples, the etchant may have the ability to remove or etch a variety of other materials such as metals (e.g., W, Ti, Mo, Co, or Ta, or the like, or a combination thereof), oxides (e.g., Al2O3, HfO2, ZrO2, ZnO, or TiO2, or the like, or a combination thereof) and/or silicides (e.g. MoSi, TiSi, or the like, or combinations thereof).

The cyclic deposition sub-cycle 614 may continue by purging the reaction chamber at block 1044. For example, excess halide 132 may be removed from the surface of the substrate by introducing an inert purge gas and exhausting the reaction chamber with the aid of a vacuum pump in fluid communication with the reaction chamber. In another example, a purge operation of block 1044 may be performed at any point in the cyclic etching sub-cycle 614, such as, prior to the start of cyclic etching sub-cycle 614, and/or at completion of cyclic etching sub-cycle 614, after pulsing halide reactant into the chamber at block 1024.

In some examples, during processing, the temperature of the reaction chamber 104 during the cyclic etching sub-cycle 614 may be less than about 600° C., or less than about 550° C., or less than about 500° C., or less than about 450° C., or less than about 400° C., or any appropriate temperature. The pressure of the reaction chamber 104 during the cyclic etching sub-cycle 614 may be between 0.1 and 50 Torr, or between 0.1 and 5 Torr, or between. 1 and 10 Torr, or any appropriate pressure. In an example, during the cyclic etching sub-cycle 614, a vessel temperature (e.g., halide source vessel 140) may be less than about 150° C., or less than about 140° C., or less than about 130° C., or less than about 120° C., or less than about 110° C., or between about 100° C.-150° C., or any appropriate temperature. In an example, the vessel (e.g., halide source vessel 140) temperature during the cyclic etching sub-cycle 614 may be higher than the temperature of respective reactant source vessels during cyclic deposition sub-cycle 612 and/or the cyclic deposition sub-cycle 612, providing a faster etching rate.

At block 1050, if the desired (i.e., predetermined) thickness of base 322 has not been achieved then cyclic deposition sub-cycle 614 may be repeated any number of times (see arrow 605 returning to block 1024) appropriate to etch back the thickness of the first layer to the desired thickness of base 322.

At block 1050, it may be determined whether base 322 has been etched to desired thickness. If not, cyclic deposition sub-cycle 614 may repeat at step 1005. If desired thickness of base 322 has been achieved, process 1000 may move to an operation at block 6 16 where a metal (or other material) may be deposited on base 322. Process block 616 may comprise one or more deposition sub-cycles that may be repeated until a second layer (e.g., second layer 330 shown in FIG. 3) reaches a predetermined thickness. At block 618, process 1000 may end.

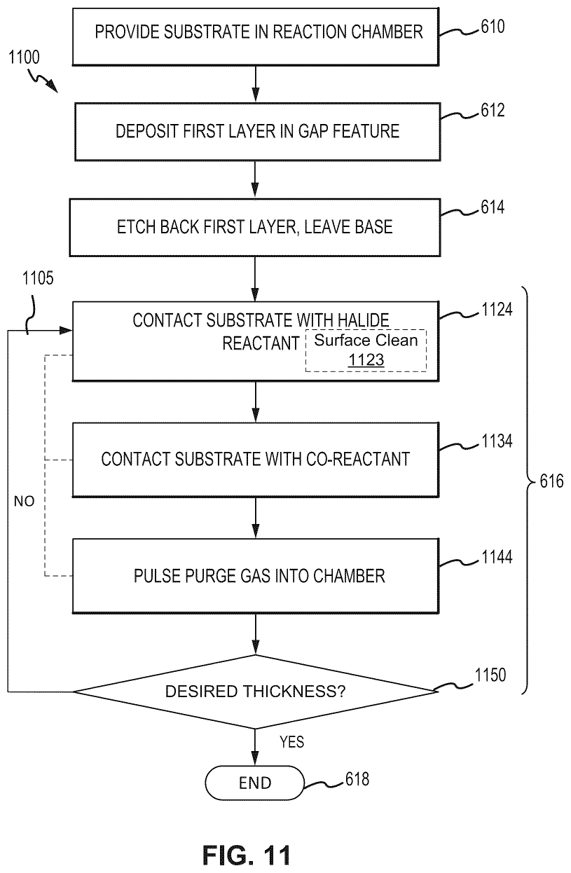

FIG. 11 illustrates an example of a cyclic deposition process 1100 for partially or completely filling one or more gap features on a substrate according to various examples of the disclosure.

In an example, process 1100 may begin with process block 610 where a substrate (e.g., substrate 310 shown in FIG. 3) comprising a gap feature (e.g., gap feature 304 of FIG. 3) is supported in a reaction chamber (e.g., chamber 104 shown in FIG. 1). First layer (e.g., first layer 320 shown in FIG. 3) may be deposited to a desired thickness within a gap feature (e.g., gap feature 304 of FIG. 3) of the substrate by a cyclic deposition sub-cycle represented in block 612 and described above, at least, with reference to FIGS. 7-9.

In an example, process 1100 may proceed to a cyclic etching operation at block 614, which may be repeated to etch back first layer 320 to form a base (e.g., base 322 shown in FIG. 3). Upon etching base 322 to a desired thickness, process 1100 may move to a cyclic deposition sub-cycle 616 (expanding block 616 from FIG. 6) where a metal (or other material) may be deposited on base 322.

In an example, cyclic deposition sub-cycle 616 is a selective bottom-up filling process for filling one or more gap features on a surface of a substrate. Cyclic deposition sub-cycle 616 may be repeated until a second layer (e.g., second layer 330 shown in FIG. 3) is deposited on a base within a gap feature of a substrate and reaches a predetermined thickness.

In an example, the process may begin with an optional surface clean step at block 1123 that may involve performing a surface clean on a semiconductor device structure to remove metal oxides from a metal film/layer/element on a bottom surface or a base of a gap feature. Before depositing a second layer within the gap feature surface cleaning may be performed, for example, using H2-based plasma cleaning techniques in a direct plasma or a remote plasma source that are designed to remove metal oxides.

Alternatively or additionally, in some examples, surface clean may be performed with an etch step to remove residues (e.g., Cl-related) that may tend to accumulate in features 304 and are difficult to remove. These residues may become trapped after second layer 330 deposition (e.g., with Mo) on top of the base 322. The etch step may comprise exposing etched first layer 320 to low power NF3 133 plasma for several seconds after thermal etch back in cyclic etching sub-cycle 614. By adjusting the NF3 133 flow, the plasma power can be controlled and so too can the resulting etch rate. By optimizing the timing of the NF3 plasma treatment, it may be possible to significantly minimize the formation of interface voids.

Process 1100 may continue to block 1124 involving providing a metal precursor into the reaction chamber for a pulse period. The metal precursor may be a halide (e.g., halide 132 shown in FIG. 1) and may take a variety of forms including but not limited to MoCl5, MoCl4, MoO2Cl2 and/or MoOCl4. At block 1144, a purge gas 124 may be pulsed into the reaction chamber to remove excess reactant.

Concurrently or separately, at block 1134, a co-reactant may be pulsed into the chamber to contact substrate. The reactant may take a variety of forms with a reducing agent such as H2 used in some implementations.

At block 1134, the substrate may be contacted with a co-reactant (e.g., precursor 134 acting as co-reactant shown in FIG. 1). The co-reactant may be a reducing agent and may be pulsed into the chamber before, after, and/or simultaneously with the halide species. In some embodiments, a ratio of the halide (e.g., MoCl5) to co-reactant may be tailored to achieve a specific deposition rate, for example, a MoCl5:H2 ratio of about 1*10E-5 to 1*10E-3 is desirable in particular examples.

In an example, the precursor 134 may include, but is not limited to: H2 and N2, ammonia (NH3), hydrazine (N2H4), an alkyl-hydrazine, an alcohol, an aldehyde, a carboxylic acid, a borane, and an amine, silane (SiH4), disilane (Si2H6), trisilane (Si3H8), germane (GeH4), digermane (Ge2H6), borane (BH3), diborane (B2H6), 1-methyl-3,6-bis(trimethylsilyl)-1,4-cyclohexadiene (C13H26Si2) and hydrogen excited species.

At block 1150 it may be determined whether after each cyclic deposition sub-cycle 616, the second layer reached a desired thickness (e.g., predetermined thickness). If not, additional cycles may be performed at step 1105 to further increase the thickness of the second layer being grown to bottom-up fill the gap feature.

Operations at blocks 1123, 1124, and/or 1134 may be carried out in any order, be skipped, repeated, and/or be separated by one or more purge operations at block 1144, and claimed subject matter is not limited in this regard. When the second layer reaches the predetermined or desired thickness, process 1100 may proceed to block 618, where process 1100 may end.

In some examples, during processing, the temperature of the reaction chamber 104 during cyclic deposition sub-cycle 616 may be less than about 600° C., or less than about 550° C., or less than about 500° C., or less than about 450° C., or less than about 400° C. or between about 400° C.-550° C., or any appropriate temperature. The pressure of the reaction chamber 104 during cyclic deposition sub-cycle 616 may be between 0.1 and 100 Torr, or between 0.1 and 50 Torr, or between 0.1 and 25 Torr, or any appropriate pressure. In an example, during cyclic deposition sub-cycle 616 a vessel (e.g., reactant source vessel 140) temperature may be less than about 110° C., or less than about 100° C., or less than about 90° C., or less than about 80° C., or between about between 80° C.-110° C., or any appropriate temperature.

It should be appreciated that any conceivable sequence of the deposition, etching processes, purge cycles, and repetitions thereof, is assumed as part of the present disclosure including combinations of deposition, etching processes, purge cycles, and repetitions thereof disclosed with respect to different FIGS. and claimed subject matter is not limited in this regard.

Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A method for filling a gap feature on a substrate surface, comprising:
providing a substrate with a surface comprising a gap feature in a reaction chamber;
depositing a first material layer into the gap feature with a first cyclic deposition process;
etching the first material layer to form a base in a bottom portion of the gap feature with a cyclic etching process; and
partially filling the gap feature with a second material layer with a second cyclic deposition process.

2. The method of claim 1, wherein the base is a metal base comprising a metal selected from the group consisting of titanium nitride (TiN), molybdenum nitride (MoN), tungsten nitride (WN), vanadium nitride (VN), niobium nitride (NbN), tantalum nitride (TaN), hafnium nitride (HfN), zirconium nitride (ZrN), molybdenum (Mo), tungsten (W), fluorine-free W (FFW), ruthenium (Ru), cobalt (Co), copper (Cu), or a doped metal nitride.

3. The method of claim 1, wherein the first cyclic deposition process comprises:
contacting the substrate with a first vapor phase precursor;
contacting the substrate with a second vapor phase precursor; and
purging the chamber.

4. The method of claim 3, wherein the first vapor phase precursor comprises at least one of titanium tetrachloride (TiCl₄), titanium tetraiodide (TiI₄), titanium tetrabromide (TiBr3), hafnium tetrachloride (HfCl₄), boron trichloride (BCl₃), aluminum trichloride (AlCl₃), silicon tetrachloride (SiCl₄), disilicon hexachloride (Si₂Cl₆), trisilicon octochloride (Si₃Cl₈), dichlorosilane (SiH₂Cl₂), NiCl₂ (TMPDA), 2-methylcyclohexa-2,5-diene-1,4-diyl)bis(trimethylsilane) (C13H26Si2), triethyl borate (B(OCH2CH3)3), gallium monochloride (GaCl), gallium trichloride (GaCl₃), niobium pentachloride (NbCl₅), molybdenum tetrachloride (MoCl₄), molybdenum pentachloride (MoCl₅), molybdenum (V) trichloride oxide (MoOCl₃), molybdenum (VI) tetrachloride oxide (MoOCl₄), molybdenum (IV) dichloride dioxide (MoO₂Cl₂), indium trichloride (InCl₃), tantalum pentachloride (TaCl₅), tungsten hexachloride (WCl6), vanadium fluoride (VF3), vanadium chloride (VCl3), vanadium oxychloride (VOCl3), or zirconium tetrachloride (ZrCl4), or combinations thereof.

5. The method of claim 3, wherein the second vapor phase precursor comprises at least one of hydrogen (H2), molecular nitrogen (N₂), ammonia (NH₃), hydrazine (N₂H₄), a hydrazine derivative, a nitrogen-based plasma, an alkyl-hydrazine, tertbutylhydrazine (C₄H₉N₂H₃), methylhydrazine (CH₃NHNH₂), dimethylhydrazine ((CH₃)₂N₂H₂), atomic nitrogen (N), nitrogen ions, nitrogen radicals, or excited species of nitrogen.

6. The method of claim 3, further comprising contacting a top portion of the substrate with an inhibitor.

7. The method of claim 6, wherein the inhibitor comprises at least one of allyltrimethylsilane (TMS-A), chlorotrimethylsilane (TMS-Cl), N-(trimethylsilyl)imidazole (TMS-Im), octadecyltrichlorosilane (ODTCS), hexamethyldisilazane (HMDS), N-(trimethylsilyl) dimethylamine (TMSDMA) or trimethylchlorosilane, or a combination thereof.

8. The method of claim 3, further comprising contacting an exposed surface of the first material layer with an oxidizer.

9. The method of claim 8, wherein the oxidizer comprises at least one of: water (H2O), hydrogen peroxide (H2O2), ozone (O3), oxygen (O2), O2 plasma, alcohol, alkyl alcohol, ethanol, methanol, butanol, isobutanol, isopropanol, or a combination thereof.

10. The method of claim 1, wherein the cyclic etching process comprises:
a. contacting the substrate with a first halide; and
b. purging the chamber.

11. The method of claim 10, wherein the first halide comprises molybdenum pentachloride (MoCl5), NF3, tungsten chloride (WCl5), chlorine (C12), niobium chloride (NbCl5), titanium tetrachloride (TiCl4), vanadium tetrachloride (VCl4), tantalum pentachloride (TaCl5), hafnium tetrachloride (HfCl4), niobium fluoride (NbF5), or tantalum fluoride (TaF5), or a combination thereof.

12. The method of claim 11, wherein the first halide comprises MoCl5, NF3, NbCl5 or WCl5.

13. The method of claim 10, wherein a first halide vessel temperature is between 100° C.-150° C.

14. The method of claim 10, wherein the second cyclic deposition process comprises:
contacting the substrate with a second halide;
contacting the substrate with co-reactant; and
purging the chamber.

15. The method of claim 14, wherein the second halide comprises at least one MoCl5, MoCl4, MoO2Cl2 or MoOCl4.

16. The method of claim 14, wherein the first halide and the second halide are the same.

17. The method of claim 14, further comprising a surface clean step including contacting an exposed surface within the gap feature with an etching gas.

18. The method of claim 17, wherein the etching gas is a plasma of NF3.

19. The method of claim 14, wherein the co-reactant comprises at least one of H2, N2, ammonia (NH3), hydrazine (N2H4), silane (SiH4), disilane (Si2H6), trisilane (Si3H8), germane (GeH4), digermane (Ge2H6), borane (BH3), diborane (B2H6), 1-methyl-3,6-bis(trimethylsilyl)-1,4-cyclohexadiene (C13H26Si2) or hydrogen excited species.

20. The method of claim 14, wherein the co-reactant comprises H2.
